(19) United States
(12) Patent Application Publication
(10) Pub. No.: US 2026/0006935 A1
(43) Pub. Date: Jan. 1, 2026

(54) METHOD FOR MANUFACTURING AN OPTOELECTRONIC DEVICE COMPRISING AN LED AND A PHOTODIODE

(71) Applicant: Commissariat à I'Énergie Atomique et aux Énergies Alternatives, Paris (FR)

(72) Inventors: Julia Simon, Grenoble (FR); Fabian Rol, Grenoble (FR); Patrick Le Maitre, Grenoble (FR)

(73) Assignee: Commissariat à I'Énergie Atomique et aux Énergies Alternatives, Paris (FR)

(21) Appl. No.: 19/135,042

(22) PCT Filed: Nov. 30, 2023
(86) PCT No.: PCT/EP2023/083766

§ 371 Date: Jun. 2, 2025

(30) Foreign Application Priority Data
Dec. 7, 2022 (FR) FR2212871

(51) Int. Cl. H10F 55/00; H10F 71/00; H10H 29/01; H10H 29/03; H10H 29/14; H10H 29/85

(52) U.S. Cl. CPC H10F 55/00; H10F 71/137; H10H 29/011; H10H 29/03; H10H 29/142; H10H 29/857

(57) ABSTRACT

A a method for manufacturing an optoelectronic device including at least one LED and at least one photodiode, including the following consecutive steps: a) epitaxially forming an active semiconductor emitting and receiving stack common to the LED and photodiode; b) forming trenches extending vertically through the active stack, and laterally delimiting the LED and photodiode, wherein the trenches are arranged so that the lateral dimensions of the LED are smaller than the lateral dimensions of the photodiode.

The present application is based on, and claims the priority of, the French patent application FR2212871 filed on Dec. 7, 2022, and entitled “Procédé de fabrication d'un dispositif optoélectronique comprenant une LED et une photodiode”, which is considered an integral part of the present description to the extent provided by law.

### TECHNICAL FIELD

The present disclosure generally relates to the field of optoelectronic devices. More specifically, it concerns the implementation of an optoelectronic device including at least one light-emitting diode (LED) and at least one photodiode. In particular, it concerns concurrently implementing, by means of a common epitaxy step, an active emitting stack of the LED and an active receiving stack of the photodiode, intended to operate in the same wavelength range.

### BACKGROUND ART

Already proposed, for example in the field of optical communication systems, are devices comprising one or more LEDs configured to emit light signals, and one or more photodiodes configured to receive and measure signals emitted by the LEDs.

It would be desirable to be able to improve at least in part some aspects of these systems.

In particular, it would be desirable to be able to concurrently perform, by means of a common epitaxy step, an active emitting stack of the LED and an active receiving stack of the photodiode.

### SUMMARY OF INVENTION

To this end, one embodiment provides a method for manufacturing an optoelectronic device including at least one LED and at least one photodiode, comprising the following successive steps:
a) epitaxially forming an active semiconductor emitting and receiving stack common to the LED and photodiode;
b) forming trenches extending vertically through the active stack, and laterally delimiting the LED and photodiode,
wherein the trenches are arranged so that the lateral dimensions of the LED are smaller than the lateral dimensions of the photodiode.

According to one embodiment, the trenches are arranged so that the lateral dimensions of the LED are at least half the lateral dimensions of the photodiode.

According to one embodiment, the trenches are arranged so that the lateral dimensions of the LED are at least four times smaller than the lateral dimensions of the photodiode.

According to one embodiment, the trenches are arranged so that the lateral dimensions of the LED are less than 4 um.

According to one embodiment, the method comprises, between step a) and step b), a step for transferring and attaching the active stack to a face of a control integrated circuit previously formed in and on a semiconductor substrate.

According to one embodiment, during the step for transferring and attaching, the active stack is attached to the said face of the control integrated circuit by molecular bonding.

According to one embodiment, at the end of the step for transferring and attaching, the active stack extends continuously over the entire surface of the control integrated circuit.

According to one embodiment, the active semiconductor stack comprises one or more type III-V or II-VI semiconductor alloys.

Another embodiment provides an optoelectronic device including at least one LED and at least one photodiode, each comprising an active semiconductor emitting and receiving stack of the same nature and composition, the lateral dimensions of the LED being smaller than the lateral dimensions of the photodiode.

According to one embodiment, the device further comprises a control integrated circuit on one face of which the LED and photodiode are attached, the control integrated circuit being suitable for driving the LED with a higher current density than that of the photodiode.

According to one embodiment, the control integrated circuit is suitable for driving the LED with a current density at least ten times higher than that of the photodiode.

Another embodiment provides a method for manufacturing an optoelectronic device including at least one LED and at least one photodiode, comprising the following steps:
a) forming a semiconductor supporting stack comprising at least one doped semiconductor layer;
b) concurrently forming, in a common epitaxy step, an active semiconductor emitting stack of the LED and an active semiconductor receiving stack of the photodiode;
c) forming trenches extending vertically through the supporting stack and laterally delimiting at least one first supporting pad and at least one second supporting pad,
wherein, at the end of steps b) and c), the active semiconductor emitting stack of the LED covers the first supporting pad and the photodiode active receiving stack covers the second supporting pad,
the method further comprising, after step c), a step d) for porosifying said doped semiconductor layer in the first supporting pad without porosifying said doped semiconductor layer in the second supporting pad, or a step for porosifying said doped semiconductor layer in the second supporting pad without porosifying said doped semiconductor layer in the first supporting pad.

According to one embodiment, step c) for forming trenches through the supporting stack and step d) for porosifying of the doped semiconductor layer are performed prior to step b) for epitaxially growing the active emitting semiconductor stack of the LED and the active receiving semiconductor stack of the photodiode, and wherein, in step d), said doped semiconductor layer is porosified in the second supporting pad, and is not porosified in the first supporting pad.

According to one embodiment, step c) for forming trenches through the supporting stack is performed after step b) for epitaxially growing the emitting semiconductor active stack of the LED and the receiving semiconductor active stack of the photodiode, and, in step d), said doped semiconductor layer is porosified in the first supporting pad and not in the second supporting pad.

According to one embodiment, in step d), the flanks of the doped semiconductor layer in the second pad are brought into contact with the electrolyte, while the flanks of the doped semiconductor layer in the first pad are protected from contact with the electrolyte by a protective layer.

According to one embodiment, in step d), the flanks of the doped semiconductor layer in the first pad are brought into contact with an electrolyte, while the flanks of the doped semiconductor layer in the second pad are protected from contact with the electrolyte by a protective layer.

According to one embodiment, in step d), a bias current is applied through said doped semiconductor layer.

According to one embodiment, the method comprises, after steps b) and d), a step for transferring and attaching the LED and photodiode to one face of a control integrated circuit previously formed in and on a semiconductor substrate.

According to one embodiment, during the step for transferring and attaching, the LED and photodiode are attached to the face of the control integrated circuit by molecular bonding.

According to one embodiment, the trenches are arranged so that the lateral dimensions of the LED are smaller than the lateral dimensions of the photodiode.

According to one embodiment, the active semiconductor emitting stack of the LED and the active semiconductor receiving stack of the photodiode comprise one or more type III-V or II-VI semiconductor alloys.

Another embodiment provides an optoelectronic device including at least one LED comprising an active semiconductor emitting stack and at least one photodiode comprising an active semiconductor receiving stack, the device further comprising a doped semiconductor layer opposite the LED and the photodiode, wherein the doped semiconductor layer is porous opposite the LED and non-porous opposite the photodiode, or wherein the doped semiconductor layer is porous opposite the photodiode and non-porous opposite the LED.

According to one embodiment, the device further comprises a control integrated circuit on one face of which the LED and photodiode are attached, the control integrated circuit being suitable for driving the LED with a higher current density than that of the photodiode.

According to one embodiment, the control integrated circuit is suitable for driving the LED with a current density at least ten times higher than that of the photodiode.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1A, FIG. 1B, FIG. 1C, and FIG. 1D are cross-sectional views illustrating steps in an example implementation of a method for manufacturing an optoelectronic device according to a first embodiment;

FIG. 2A, FIG. 2B, FIG. 2C, FIG. 2D, FIG. 2E, and FIG. 2F are cross-sectional views illustrating steps in an example implementation of a method for manufacturing an optoelectronic device according to a second embodiment;

FIG. 3A, FIG. 3B, FIG. 3C, FIG. 3D, and FIG. 3E are cross-sectional views illustrating steps in an example implementation of a method for manufacturing an optoelectronic device according to a third embodiment; and

FIG. 4 is a diagram illustrating the response of an active emitting stack of the LED and of an active receiving stack of the photodiode produced by means of a common epitaxy step.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the implementation of the electrical connections and LED and photodiode control circuits of the described devices have not been described in detail, the described embodiments being compatible with the usual implementations of these elements, or the implementation of these elements being within the scope of those skilled in the art from the indications of the present description. Further, the applications likely to benefit from the described embodiments have not been described in detail, as the embodiments described can advantageously be used for any application including one or more LEDs and one or more photodiodes intended to operate in the same wavelength range, for example a visible, ultraviolet, or near-infrared light wavelength range.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

According to one aspect of the described embodiments, is provided a method for manufacturing an optoelectronic device wherein an active emitting stack of the LED and an active photosensitive stack of the photodiode are concurrently implemented in a single epitaxy step.

One advantage lies in the cost reduction compared with methods comprising separate particular epitaxy steps to consecutively produce the active emitting stack of the LED and the active receiving stack of the photodiode.

The LED and photodiode can be monolithically integrated into a single optoelectronic chip, or separated by cutting at the end of the method for integration into separate chips, for assembly into a same optoelectronic device.

The active emitting stack of the LED and the active receiving stack of the photodiode are, for example, inorganic semiconductor stacks, for example based on III-V semiconductor materials, for example based on group III nitrides, e.g. gallium, aluminum, indium or an alloy based on one or more of these materials. Alternatively, the active emitting stack of the LED and the active receiving stack of the photodiode are based on type II-VI semiconductor materials, e.g. ZnCdSe (zinc-cadmium-selenium).

The same gallium nitride-based active stack can, for example, be used as an active stack of the LED at emission, or as an active stack of the photodiode at reception. The photodiode thus has a very low dark current and a narrow optical bandwidth at reception, allowing a very good signal-to-noise ratio to be obtained.

However, one difficulty lies in the fact that the optimum emitting wavelength of the LED (transmitting peak) is shifted upwards by a few tens of nanometers, typically around 20 nm for a gallium nitride (GaN)-based active stack, for example based on indium-gallium nitride (InGaN), compared with the optimum receiving wavelength of the photodiode (absorption peak). This is known as the Stokes shift, and is caused in particular by the binding energy of electron-hole pairs. This affects the sensitivity of the photodiode in the LED emitting wavelength range, and consequently the efficiency of the LED-photodiode system.

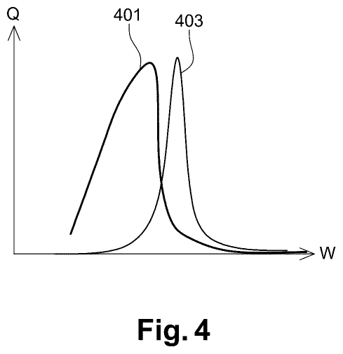

This phenomenon is particularly illustrated in FIG. 4.

FIG. 4 is a diagram showing the evolution, as a function of wavelength W (x-axis), of the quantum efficiency Q in reception (curve 401) and in emission (curve 403) of an active stack of the diode based on gallium nitride (GaN), for example based on indium-gallium nitride (InGaN).

According to one aspect of a first embodiment, one provides forming an active semiconductor stack common to the LED and photodiode by epitaxy, and then forming trenches extending vertically through the active stack and laterally delimiting the LED and photodiode. According to the first embodiment, the LED has smaller lateral dimensions than the photodiode. This allows mechanical stresses in the active stack of the LED to be relaxed to a greater extent than in the active stack of the photodiode. Thereby the internal electric field in the active stack of the LED is reduced compared with the internal electric field in the active stack of the photodiode. This reduction in the internal electric field in the active stack of the LED results in downwards shift (so called blue-shift) of the emission peak of the LED. This allows the Stokes shift between the emission peak and the absorption peak of the active stack to be at least partially compensated. The emission peak of the LED is thus brought closer to the absorption peak of the photodiode, improving system efficiency.

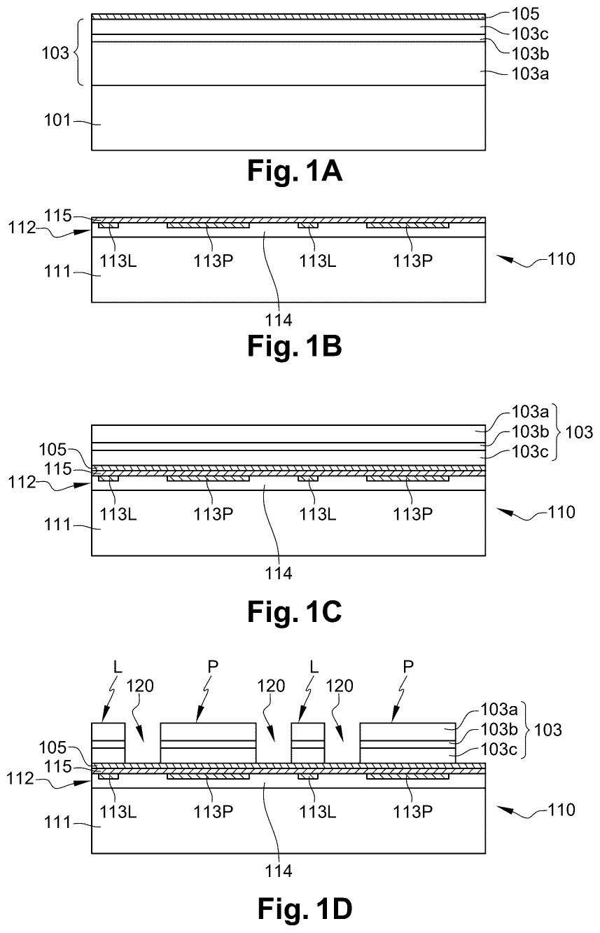

FIGS. 1A to 1D are cross-sectional views schematically illustrating steps in an example embodiment of a method for manufacturing an optoelectronic device according to the first embodiment.

FIG. 1A illustrates a structure including an active semiconductor emitting and receiving stack 103 arranged on the top face of a supporting substrate 101.

The active stack 103 comprises, for example, a semiconductor layer 103a doped with a first conductivity type, for example N-type, coating the top face of the substrate 101, an active layer 103b coating the face of the layer 103a opposite the substrate 101, i.e. its top face in the orientation shown in FIG. 1A, and a semiconductor layer 103c doped with a second conductivity type, for example P-type, coating the face of layer 103b opposite layer 103a, i.e. its top face in the orientation shown in FIG. 1A. By way of example, layer 103b is in contact, via its bottom face, with the top face of layer 103a, and, via its top face, with the lower face of layer 103c.

The layers 103a, 103b, and 103c of the active stack 103, for example, each extend continuously and with a substantially uniform thickness over the entire surface of the substrate 101.

Layers 103a, 103b, and 103c, for example, are formed consecutively by epitaxy on the top face of the supporting substrate 101.

By way of example, the supporting substrate 101 is made of sapphire or silicon. The semiconductor layers 103a and 103c of the active stack 103 are for example made of gallium nitride. For example, active layer 103b comprises a stack of layers each forming a quantum well, for example based on indium gallium nitride (InGaN).

A buffer layer, not illustrated, can form an interface between the top face of the substrate 101 and the bottom face of the lower layer 103a.

FIG. 1A further illustrates a step for depositing a metal layer 105 on the top face of the active stack 103. In the example shown, layer 105 extends continuously and with a substantially uniform thickness over the entire top surface of active stack 103. By way of example, layer 105 is in contact, via its bottom face, with the top face of the top layer 103c of the active stack.

FIG. 1B schematically illustrates an integrated control circuit 110, previously formed in and on a semiconductor substrate 111, for example a silicon substrate. In this example, the control circuit 110 comprises, on the side of its top face, for each of the LEDs of the device, a metal connection pad 113L intended to connect to one of the electrodes (anode or cathode) of the LED, so as to be able to control a current flowing through the LED and/or apply a voltage across the terminals of the LED. In this example, the control circuit 110 further comprises, on the side of its top face, for each of the photodiodes of the device, a metal connection pad 113P intended to connect to one of the electrodes (anode or cathode) of the photodiode, so as to be able to read an electrical signal representative of the intensity of light radiation received by the photodiode in its sensitivity wavelength range.

The control circuit comprises, for example, for each LED, connected to the metal pad 113L dedicated to the LED, an elementary control cell including one or more transistors, enabling the current flowing through the LED and/or a voltage applied across the terminals of the LED to be controlled, and, for each photodiode, connected to the metal pad 113P dedicated to the photodiode, an elementary sense cell comprising one or more transistors, enabling an electrical signal representative of the intensity of light radiation received by the photodiode in its sensitivity wavelength range to be read. The reading circuit comprises, for example, a transimpedance amplifier used to amplify the photodiode current.

The control circuit 110 is, for example, based on CMOS technology. The metal pads 113L, 113P can be laterally surrounded by an insulating material 114, for example silicon oxide, so that the control circuit 110 has a substantially flat top surface comprising alternating metal regions 113 and insulating regions 114. Contact to the electrodes of LEDs or photodiodes not connected to pads 113L, 113P, can be made collectively, for example in a peripheral region of control circuit 110, via one or more connection pads (not visible in the figure) of control circuit 110. By way of example, the control circuit 110 comprises, on the side of the top face of the substrate 111, a stack of insulating and conducting levels forming an interconnection network 112 comprising in particular the connection pads 113L, 113P, the top face of the interconnection network 112 defining the top face of the circuit 110.

FIG. 1B further illustrates a step for depositing a metal layer 115 is deposited on the top face of the control integrated circuit 110. In the example shown, layer 115 extends continuously and with a substantially uniform thickness over the entire top surface of circuit 110. By way of example, layer 115 is in contact, via its bottom face, with the top face of the interconnection network 112 of control circuit 110.

For example, layer 115 is made of the same material as layer 105. By way of example, layers 105 and 115 each comprise a top layer referred to as bonding layer. The bonding layers of layers 105 and 115 are preferably made of the same material, e.g. titanium.

FIG. 1C illustrates the structure obtained at the end of a step for transferring the active stack of the LED and photodiode 103 to the top face of the control circuit 110. To this end, the structure shown in FIG. 1A can be turned upside down and then transferred to the structure shown in FIG. 1B, so as to bring the face of the metal layer 105 opposite to the substrate 101 (i.e. its bottom face in the orientation shown in FIG. 1C, corresponding to its top face in the orientation shown in FIG. 1A) into contact with the face of the metal layer 115 opposite to the substrate 111 (i.e. its top face in the orientation shown in FIGS. 1B and 1C). During this step, the active stack 103 is bonded to the control circuit 110. By way of example, attaching the active stack 103 to the control circuit 110 can be obtained by molecular bonding between the two surfaces brought into contact. Alternatively, attaching the two surfaces can be performed by thermocompression, eutectic bonding, or any other suitable bonding method.

Once bonding is complete, the supporting substrate 101 is removed so as to expose the top face (in the orientation shown in FIG. 1C) of the semiconductor layer 103c of the active stack 103. The substrate 101 is removed, for example, by grinding and/or etching from its face opposite to the active stack 103. Alternatively, in the case of a transparent substrate 101, for example a sapphire substrate, the substrate 101 can be detached from the active stack 103 by means of a laser beam projected through the substrate 101 from its face opposite to the active stack 103 (laser lift-off type method). More generally, can be used any other method allowing the substrate 101 to be removed. After substrate removal, an additional etching step can be provided to remove any buffer layers remaining on the top face side of semiconductor layer 103c. Further, part of the thickness of layer 103c can be removed, for example by etching. At the end of this step, the active stack 103 covers substantially the entire surface of the control circuit 110, without discontinuity. By way of example, the thickness of active stack 103 at the end of the step shown in FIG. 1D is between 0.5 and 2 μm.

At the end of this step, the mechanical stresses of the epitaxially grown active stack 103 are partially transferred to the substrate 111 of the control circuit 110.

FIG. 1D illustrates a step subsequent to the step shown in FIG. 1C, during which trenches 120 are formed in the active stack 103, from its top face, for example by lithography followed by etching, so as to delimit one or more LEDs L and one or more photodiodes P, each corresponding to an island or mesa-shaped portion of the active stack 103. In the example shown, the trenches 120 extend vertically over the entire height of the active stack 103 and open onto the top face of the metal layer 105. The trenches 120 can be aligned with marks previously formed on the control circuit 110. In the example shown, each LED L is located, in vertical projection, opposite a single metal pad 113L on the control circuit 110, and each photodiode P is located, in vertical projection, opposite a single metal pad 113P on the control circuit 110. By way of example, each LED L and each photodiode P has, in plan view, a substantially square or rectangular shape. For example, when viewed from above, the trenches 120 form a grid or grid pattern separating the LEDs L and photodiodes P of the device laterally from one another.

The trenches can then be extended through the metal layers 105 and 115 to individualize the electrical connections on the lower semiconductor layer 103c of the active stack 103 of each LED L and each photodiode P. Subsequent steps can then be implemented to resume individual or common electrical contact on the upper semiconductor layer 103a of the active stack 103 of each LED L and each photodiode P. These steps have not been described in detail and are within the scope of those skilled in the art from the indications of the present description. By way of example, these steps are similar to what has been described in patent application WO2017194845 or in patent application WO2019092357 previously filed by the applicant.

During the step for etching the active stack 103 shown in FIG. 1D, an additional relaxation of the mechanical stresses present in the epitaxially grown active stack 103 occurs via the edges of the etched islands or mesas. This relaxation depends on the size of the islands or mesas. In particular, islands or mesas with small dimensions exhibit high stress relaxation, while islands or mesas with larger dimensions retain relatively high mechanical stress. Relaxation may further depend on the nature of the substrate, which may for example comprise a stack of a gallium nitride layer on a silicon layer, or a stack of a gallium nitride layer on a sapphire layer, or a stack of a porous gallium nitride layer on a silicon layer.

According to one aspect of the first embodiment, one provides defining:
LEDs L with relatively small lateral dimensions, so as to obtain a significant relaxation of mechanical stresses in the active stack 103 and consequently a relatively large downward shift of the emission peak, and
photodiodes P with relatively large lateral dimensions, so as to achieve less relaxation of mechanical stresses in the active stack 103, and consequently a relatively low downward shift of the absorption peak.

This allows the Stokes shift naturally present between the emission peak and the absorption peak of the active stack 103 to be at least partially compensated.

By way of example, the islands or mesas forming the LEDs L have lateral dimensions of less than or equal to 5 μm, for example less than or equal to 4 μm, for example less than or equal to 2 μm. This enables the active stack to be almost completely relaxed during etching the LED. For their part, the islands or mesas forming the photodiodes P have lateral dimensions greater than those of the LEDs, for example at least twice those of the LEDs, for example at least four times those of the LEDs, so as to maintain relatively high mechanical stresses in the active stack 103 of the photodiodes P.

By way of a non-limiting example, for a GaN-based active stack and for square LEDs L with sides of around 1 μm, and for photodiodes P with sides of 8-10 μm, an alignment of the emission peak of the LEDs L with the absorption peak of the photodiodes P is observed.

The embodiments described are not limited to the example of the arrangement of LEDs L and photodiodes P illustrated in FIG. 1D. By way of example, the device may comprise, on a first part of the surface of the integrated control circuit 110, a plurality of LEDs L, for example identical (except for manufacturing dispersions), for example arranged in a matrix according to rows and columns, for example with a constant inter-LED pitch. The device can further comprise, on a second part of the surface of the integrated control circuit 110, a plurality of photodiodes P, for example identical (except for manufacturing dispersions), for example arranged in a matrix according to rows and columns, for example with a constant inter-photodiodes pitch. The inter-LED pitch in the first region is, for example, identical to the inter-photodiode pitch in the second region. On the other hand, the lateral dimensions of the LEDs in the first region are smaller than the lateral dimensions of the photodiodes in the second region.

In addition to the differentiated size of the LEDs L versus the photodiodes P, another parameter enabling the wavelength shift between the emission peak of the LED and the absorption peak of the photodiodes to be reduced is the charge carrier density in the active stack and, in particular, in the quantum wells of the active layer 103b. More particularly, a high carrier density will lead to the electric field present in the active stack being shielded, and consequently to the optimal operating wavelength of the active stack being shifted downwards.

Thus, advantageously, the control circuit 110 is configured to drive the LEDs L at higher voltages than the photodiodes P. This allows a higher carrier density to be obtained in the LEDs L than in the photodiodes P, and consequently the shift between the emission peak of the LEDs L and the absorption peak of the photodiodes P to be reduced. By way of example, the drive voltages are chosen so as to have a carrier density in the LEDs L that is at least twice as high, for example at least five times as high, or of the order of ten times as high, as in the photodiodes P.

The value of the wavelength shift associated with the increase in current density in the LED depends on the structure of the active stack, and in particular on the width of the quantum wells in the active layer 103b. In particular, the wider the wells, the greater the electric field shielding associated with the increase in carrier density, and consequently the greater the downward shift in the optimum emission wavelength of the LED associated with the increase in carrier density. On the other hand, increasing the width of wells mean longer radiative recombination times, which can be detrimental for communication applications requiring short recombination times. Those skilled in the art will be able to choose the appropriate compromise according to the needs of the application. By way of an illustrative, non-limiting example, for a LED including 4 nm thick InGaN quantum wells with an indium content of 14.3%, driving the LED with a current density of the order of 100 A/cm² leads to a blue shift of the emission peak of around 6 nm compared with driving the same LED at a current density of the order of 10 A/cm².

To fully compensate for the Stokes shift, the mechanical relaxation effect described above can be combined, for example, by using LEDs that are smaller than the photodiodes, and the effect of field shielding by the carriers, by using a higher current density in the LEDs than in the photodiodes. By way of an illustrative, non-limiting example, for gallium nitride-based LEDs including InGaN quantum wells, there is a wavelength shift in the emission peak between a 4 μm-wide LED driven at a current density of the order of 200 A/cm² and a 25 μm-wide LED of the same type driven at a current density of the order of 10 A/cm², of the order of 30 nm. Of this 30 nm shift, around 20 nm is due to the difference in size, with the remainder (around 10 nm) due to the difference in current density. This shift is typically of the same order as the Stokes shift between emission and reception in the active stack.

One should note that compensation by differentiation of carrier densities between LEDs and photodiodes can also be achieved in a device with LEDs L of the same lateral dimensions as photodiodes P, or even with lateral dimensions greater than those of photodiodes P.

According to one second embodiment, prior to the common epitaxy step, during which the active emitting and receiving stacks are formed concurrently, a supporting layer of semiconductor material is porosified locally, opposite the photodiodes of the device, onto which the active stack is to be epitaxially grown. This results in a relaxation of mechanical stresses in the active stack of the photodiode during epitaxy, in particular during the formation of the active layer 103b of the stack. This relaxation leads to a difference in the proportions of the semiconductor alloy species forming the active layer 103b between the photodiodes and the LEDs. In particular, in the case where the active layer comprises InGaN quantum wells, the result is greater indium incorporation in the photodiode quantum wells than in the LED quantum wells. This leads to a red shift, i.e. an upward shift, of the absorption peak of the photodiodes, and thus at least partially compensates for the Stokes shift between the emission peak and the absorption peak of the active stack.

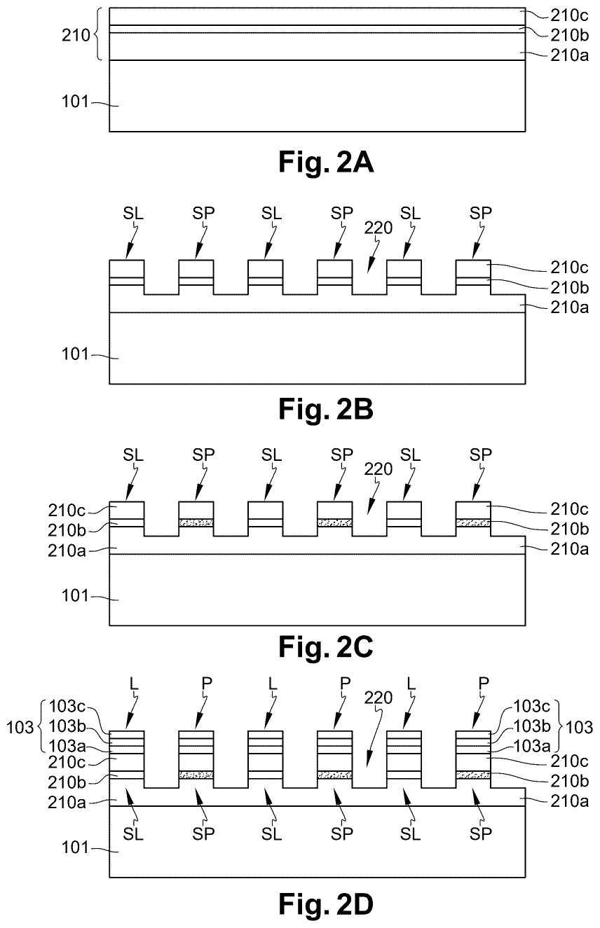

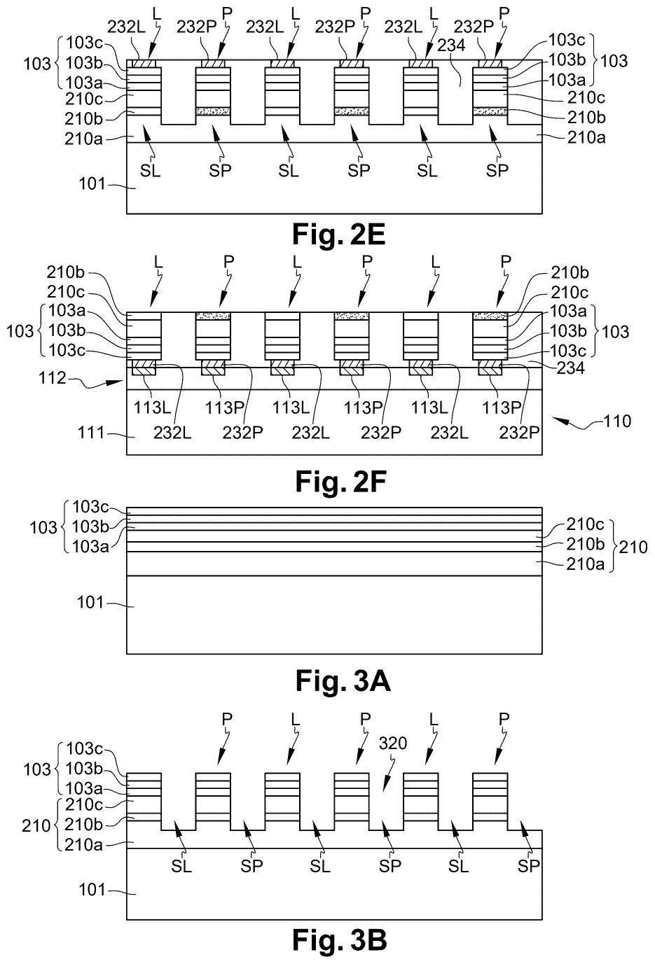

FIGS. 2A to 2F are cross-sectional views schematically illustrating steps in an example embodiment of a method for manufacturing an optoelectronic device according to the second embodiment.

FIG. 2A illustrates a structure including a semiconductor supporting stack 210 on one face of a supporting substrate 101. The supporting substrate 101 is, for example, identical or similar to that described above. The semiconductor supporting stack 210 is made, for example, of a III-V semiconductor material, such as gallium nitride. The semiconductor supporting stack 210 comprises at least one doped semiconductor layer 210b, with a doping level chosen to enable the layer 210b to be made porous during a subsequent electrolytic porosification step. By way of example, layer 210b is N-type doped. For example, layer 210b is made of N-type doped gallium nitride with a doping level of between 10¹⁹ and 1.5*10¹⁹ atoms/cm³.

In the example shown, the supporting stack 210 further comprises a semiconductor layer 210a on the bottom face of layer 210b, for example in contact with the bottom face of layer 210b. Layer 210a is made, for example, of the same material as layer 210b, but with a doping level lower than that of layer 210b, for example with a doping level at least ten times lower, at than that of layer 210b. Alternatively, layer 210a is made of a different material to layer 210b.

In the example shown, the supporting stack 210 further comprises a semiconductor layer 210c on the top face of the layer 210b, for example in contact with the top face of the layer 210b. Layer 210c is made, for example, of the same material as layer 210b but has a lower doping level than layer 210b, for example at least ten times lower, preferably at least 100 times lower, than layer 210b. Alternatively, layer 210c is made of a different material to layer 210b.

The layers 210a, 210b, and 210c of the supporting stack 210, for example, each extend continuously and with a substantially uniform thickness over the entire surface of the substrate 101.

Layers 210a, 210b, and 210c, for example, are formed consecutively by epitaxy on the top face of the supporting substrate 101.

By way of example, the supporting substrate 101 is made of sapphire or silicon. A buffer layer, not illustrated, may optionally form an interface between the top face of substrate 101 and the bottom face of the lower layer 210a of supporting stack 210.

FIG. 2B illustrates a step for forming trenches 220 in the supporting stack 210, from its top face, for example by lithography followed by etching, so as to define a plurality of island or mesa-shaped supporting pads SL and SP in the stack 210. Each supporting pad SL is intended to receive, on its top face, an LED L of the device, and each supporting pad SP is intended to receive, on its top face, a photodiode P of the device.

In the example shown, the trenches 220 extend vertically from the top face of the stack, pass entirely through layers 210c and 210b, and open into layer 210a without passing entirely through it. Alternatively, trenches 220 pass entirely through layer 210.

For example, when viewed from above, the trenches 220 form a grid or grid pattern laterally separating from each other the supporting pads SL and SP intended to receive the LEDs L and photodiodes P of the device.

For example, the supporting pads SP and SL all have the same lateral dimensions, for example between 1 μm and 25 μm, for example between 2 and 8 μm. For example, when viewed from above, the supporting pads SP and SL have a square or rectangular shape.

At this point, in each supporting pad SL and SP, the flanks of the doped semiconductor layer 210b of the supporting stack are exposed.

FIG. 2C illustrates the structure obtained at the end of a step for selectively porosifying layer 210b, located only in the supporting pads SP of the photodiodes P of the device. During this step, layer 210b of the supporting pads SP is made porous by electrolytic etching or electroporosification. Layer 210b of the supporting pads SL, on the other hand, remains non-porous.

To this end, the flanks of the supporting pads can before be coated with a protective layer (not visible in the figure), for example made of an insulating material, such as silicon oxide or nitride. The protective layer is, for example, initially deposited over the entire top face, then removed locally, for example by photolithography and etching, so as to expose the flanks of the supporting pads SP without exposing the flanks of the supporting pads SL.

The structure can then be immersed in an electrolytic bath (not visible in the figure), for example an oxalic acid-based solution, such as an aqueous oxalic acid solution.

A bias voltage is then applied so as to cause a current to flow through the doped semiconductor layer 210b. By way of example, the voltage is applied between a first electrode (not visible in the figure) connected to the layer 210a and the electrolyte (not visible in the figure) connected by the wafer to the layer 210c.

Under the effect of the bias current, the portions of layer 210b in contact with the electrolyte via their flanks, i.e. the portions of layer 210b comprised in the supporting pads SP of the photodiodes P of the device, become porous. On the other hand, the portions of layer 210b protected from contact with the electrolyte, i.e. the portions of layer 210b comprised in the supporting pads SL of the LEDs L of the device, remain intact (non-porous).

One should note that, in this example, the doping levels of layers 210a, 210b, and 210c of the supporting stack are chosen so that only layer 210b is rendered porous during the electroporosification step.

At the end of this step, the protective layer coating the flanks of the supporting pads SL can be removed.

FIG. 2D illustrates the structure obtained at the end of a common epitaxy step, during which an active semiconductor stack 103 is formed on each supporting pad SL and each supporting pad SP. The epitaxy is located, for example, in opening previously etched in a dielectric layer, not shown.

On each supporting pad SL and SP, for example, the active stack 103 covers the entire top surface of the pad. The portion of active stack 103 covering each SL pad defines a LED of the device. The portion of active stack 103 covering each SP defines a photodiode of the device.

On each supporting pad SP and SL, the active stack 103 comprises, in order from the top surface of the pad, a semiconductor layer 103a, a semiconductor layer 103b, and a semiconductor layer 103c, for example identical or similar to what has been described previously in relation to FIGS. 1A to 1D. Layers 103a, 103b, and 103c are, for example, formed consecutively by epitaxy from the top face of pads SP and SL. By way of example, in each pad SP and SL, the lower semiconductor layer 103a of the active stack 103 is in contact, via its bottom face, with the top face of layer 210c.

The presence of the porous layer 210b in the supporting pads SP results in greater mechanical relaxation in the active stack of photodiodes P than in the active stack of LEDs L. Thereby, during epitaxy, different species are incorporated into the active layer 103b of the active stack of LEDs L and the active layer 103b of the active stack of photodiodes P. In particular, in the case of an InGaN-based active layer 103b, this results in greater indium incorporation in the active layer 103b of the photodiodes P than in the active layer 103b of the LEDs L. The presence of the porous layer 210b in the supporting pads SP of the photodiodes P thus shifts the absorption peak of the photodiodes P upwards in wavelength (towards red), and thus brings it closer to the emission peak of the LEDs L.

FIG. 2E illustrates the structure obtained at the end of the step for forming, on each LED L, a contact metallization 232L on and in contact with the top face of the top semiconductor layer 103c of the active stack 103 of the LED, and, on each photodiode P, a contact metallization 232P on and in contact with the top face of the top semiconductor layer 103c of the active stack 103 of the photodiode.

FIG. 2E further illustrates a step for filling the trenches 220 and the space between the LEDs L and the photodiodes P with an electrically insulating material 234, for example silicon oxide.

After filling, a planarization step can be performed, for example by chemical mechanical polishing (CMP), so that the contact metallization 232L, 232P are flush with the top face of the filling material 234.

FIG. 2F illustrates a step for transferring and attaching the structure shown in FIG. 2E to a control integrated circuit 110, for example similar to that shown in FIG. 1B.

During this step, the contact metallization 232L, 232P of the structure shown in FIG. 2E are brought into contact, by their face opposite to the supporting substrate 101, with the face of the contact metallization 113L, 113P of the control circuit 110 opposite to the substrate 111.

By way of example, the structure shown in FIG. 2E is attached, and electrically connected, to the control integrated circuit 110 by molecular bonding, for example by hybrid metal-metal/oxide-oxide bonding.

Once the two structures have been assembled, the supporting substrate 101 of the structure shown in FIG. 2E can be removed. Further, all or part of the semiconductor supporting stack 210 can be removed, for example by grinding or etching.

In the example shown, layer 210a of supporting stack 210 is entirely removed, and layers 210b and 210c are retained. However, the embodiments described are not limited to this example.

Subsequent steps can then be implemented to take an individual or common electrical contact on the top semiconductor layer 103a of the active stack 103 of each LED L and photodiode P. For example, a layer of a transparent electrically conductive material, such as a transparent conductive oxide, e.g. indium tin oxide (ITO) is deposited on and in contact with the top face of the structure shown in FIG. 2F. These steps have not been described in detail and are within the scope of those skilled in the art from the indications of the present description.

Similar to what has been described above, the control circuit can optionally be configured to drive the LEDs and photodiodes with carrier densities suitable for reducing the shift between the emission peak of the LEDs and the absorption peak of the photodiodes.

According to one aspect of a third embodiment, one provides forming supporting pads SP and SL in a similar way to that described above in relation to FIGS. 2A to 2F, but the layer 210b of the supporting pads is selectively porosified only after the common epitaxy step in which the active stacks 103 of LEDs L and photodiodes P are concurrently formed. In this third embodiment, layer 210b is rendered porous in the vicinity of the LEDs L and is kept intact (non-porous) in the vicinity of the photodiodes P. This results in at least partial relaxation of mechanical stresses in the active stack of LEDs L, without applying this relaxation in the photodiodes P. This results in decreasing the internal electric field in the active stack of LED as compared to the active stack of photodiode. This decrease in the internal electric field in the active stack of LED leads to a downward shift in the emission peak of the LED. Again, this allows the Stokes shift between the emission peak and the absorption peak of the active stack to be at least partially compensated. The emission peak of the LED is thus brought closer to the absorption peak of the photodiode, improving system efficiency.

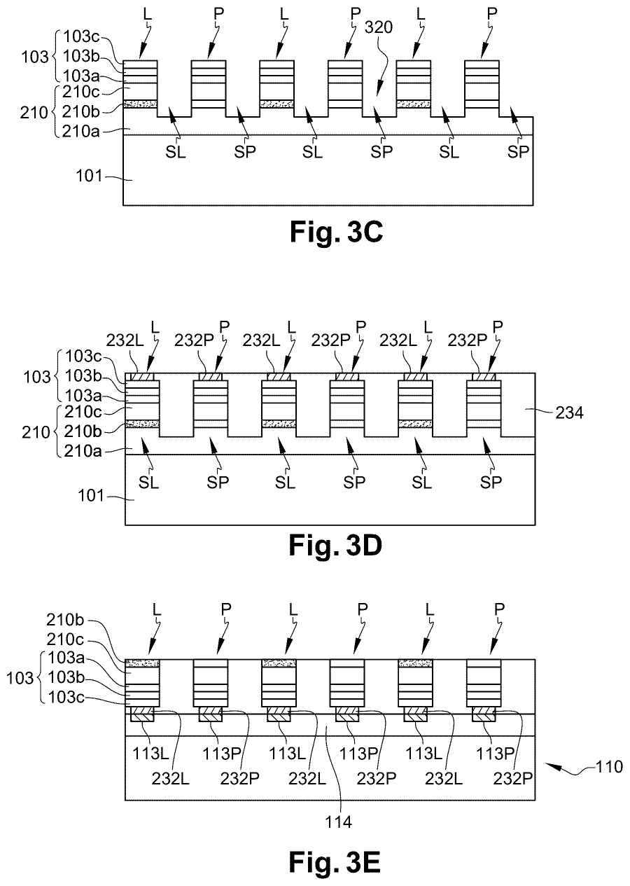

FIGS. 3A to 3E are cross-sectional views schematically illustrating steps in an example embodiment of a method for manufacturing an optoelectronic device according to the third embodiment.

FIG. 3A illustrates a structure including a semiconductor supporting stack 210 on one face of a supporting substrate 101. The supporting stack 210 and the supporting substrate 101 are for example identical or similar to what has been described previously in relation to FIG. 2A.

FIG. 3A further illustrates a step for forming an active stack 103 for LED and photodiode on the top face of the semiconductor supporting stack 210. The active stack 103 is for example identical or similar to what has been described previously, in particular in relation to FIG. 1A. Layers 103a, 103b, and 103c, for example, are formed consecutively by epitaxy from the top face of the supporting stack 210. By way of example, the lower semiconductor layer 103a of the active stack 103 is in contact, via its bottom face, with the top face of the layer 210c.

At this point, the layers of the supporting stack 210 and the layers of the active stack 103 each extend continuously and with uniform thickness over the entire surface of the supporting substrate 101.

FIG. 3B illustrates a step for forming trenches 320 in the active stack 103 and in the supporting stack 210, from the top face of the active stack 103, for example by lithography and then etching, so as to define a plurality of island- or mesa-shaped supporting pads SL and SP in the stack 210, each supporting pad SL being coated, on its top face, with a portion of the active stack 103 defining an LED L of the device, and each supporting pad SP being coated, on its top face, with a portion of the active stack 103 defining a photodiode P of the device.

In the example shown, the trenches 320 extend vertically from the top face of the active stack 103, pass entirely through the layers 103c, 103b, 103a, 210c, and 210b, and open out into the layer 210a without passing entirely through it. Alternatively, trenches 220 pass entirely through layer 210.

For example, when viewed from above, the trenches 320 form a grid or grid pattern laterally separating the LEDs L and photodiodes P from the supporting pads SL and SP.

The LEDs L and photodiodes P, and the underlying supporting pads SP and SL, for example, all have the same lateral dimensions, for example between 1 and 25 μm, for example between 2 and 8 μm. By way of example, the LEDs L and photodiodes P and the supporting pads SP and SL have, in plan view, a square or rectangular shape. More generally, the LEDs L and photodiodes P can have any shape, for example round or hexagonal.

At this point, in each supporting pad SL and SP, the flanks of the doped semiconductor layer 210b of the supporting stack are exposed.

FIG. 3C illustrates the structure obtained at the end of a step for selectively porosifying layer 210b, located only in the supporting pads SL of the LEDs L of the device. This step is similar to that previously described in relation to FIG. 2C, with the difference that, in the example of FIG. 3C, layer 210b of the supporting pads SL is rendered porous, while layer 210b of the supporting pads SP remains intact (non-porous).

To this end, during the electroporosification step, the flanks of the supporting pads SP can be protected from contact with the electrolyte by a protective layer (not visible in the figure), while the flanks of the supporting pads SL are in contact with the electrolyte.

In the example shown in FIG. 3C, the bias voltage used to force a current to pass through the layer 210b is for example applied between a first electrode (not visible in the figure) connected to layer 210a and the electrolyte (not visible in the figure) connected by the edge to layer 103c.

As a result of the porosification of layer 210b in the supporting pads SL, the mechanical relaxation is greater in the active stack of LEDs L than in the active stack of the photodiode P. This leads to downwardly shift the emission peak of the LEDs, and thus to bring it closer to the absorption peak of the photodiodes P.

FIG. 3D illustrates the structure obtained at the end of a step similar to that previously described in relation to FIG. 2E for forming, on each LED L, a contact metallization 232L on and in contact with the top face of the top semiconductor layer 103c of the active stack 103 of the LED, and, on each photodiode P, a contact metallization 232P on and in contact with the top face of the top semiconductor layer 103c of the active stack 103 of the photodiode.

FIG. 2E further illustrates a step for filling the trenches 320 and the space between the LEDs L and the photodiodes P with an electrically insulating material 234, for example silicon oxide.

After filling, a planarization step can be performed, for example by chemical mechanical polishing (CMP), so that the contact metallizations 232L, 232P are flush with the top face of the filling material 234.

FIG. 3E illustrates a step similar to that described above in relation to FIG. 2F, for transferring and attaching the structure of FIG. 3D onto a control integrated circuit 110, and removing the supporting substrate 101, and, optionally, all or part of the semiconductor supporting stack 210.

Similar to what has been described above, subsequent steps can then be implemented to take individual or common electrical contact on the top semiconductor layer 103a of the active stack 103 of each LED L and each photodiode P.

Similar to what has been described above, the control circuit can optionally be configured to drive the LEDs and photodiodes with carrier densities suitable for reducing the shift between the emission peak of the LEDs and the absorption peak of the photodiodes.

Various embodiments and variants have been described. Those skilled in the art will understand that certain features of these embodiments can be combined and other variants will readily occur to those skilled in the art. In particular, the described embodiments are not limited to the example materials and dimensions mentioned in the description.

Further, although examples of embodiments have been described above in which the active stacks 103 of the LED and photodiode are attached to the control integrated circuit by direct full-plate metal-to-metal bonding or by direct hybrid metal-to-metal/dielectric-to-electric bonding, the embodiments described are not limited to these particular examples. More generally, the active stacks 103 of the LED and photodiode can be attached to the control integrated circuit by any other means, for example by full-plate direct oxide-oxide bonding.

Furthermore, it should also be noted that the first and third embodiments can be combined.

Finally, the practical implementation of the embodiments and variants described herein is within the capabilities of those skilled in the art based on the functional description provided hereinabove.

1. A method for manufacturing an optoelectronic device including at least one LED and at least one photodiode, comprising the following consecutive steps:
a) epitaxially forming an active semiconductor emitting and receiving stack common to the LED and photodiode;
b) forming trenches extending vertically through the active stack, and laterally delimiting the LED and the photodiode,
wherein the trenches are arranged so that the lateral dimensions of the LED are smaller than the lateral dimensions of the photodiode.

2. The method according to claim 1, wherein the trenches are arranged so that the lateral dimensions of the LED are at least half the lateral dimensions of the photodiode.

3. The method according to claim 1, wherein the trenches are arranged so that the lateral dimensions of the LED are at least four times smaller than the lateral dimensions of the photodiode.

4. The method according to claim 1, wherein the trenches are arranged so that the lateral dimensions of the LED are less than 4 μm.

5. The method according to claim 1, comprising, between step a) and step b), a step for transferring and attaching the active stack to a face of a control integrated circuit previously formed in and on a semiconductor substrate.

6. The method according to claim 5, wherein during said transferring and attaching step, the active stack is attached to said face of the control integrated circuit by molecular bonding.

7. The method according to claim 5, wherein, at the end of said transferring and attaching step, the active stack extends continuously over the entire surface of the control integrated circuit.

8. The method according to claim 1, wherein the semiconductor active stack comprises one or more type III-V or II-VI semiconductor alloys.

9. An optoelectronic device including at least one LED and at least one photodiode each comprising an active semiconductor emitting and receiving stack of the same nature and composition, wherein the lateral dimensions of the LED are smaller than the lateral dimensions of the photodiode.

10. The device according to claim 9, further comprising a control integrated circuit on one face of which the LED and the photodiode are attached, the control integrated circuit being suitable for driving the LED with a higher current density than that of the photodiode.

11. The device according to claim 10, wherein the control integrated circuit is suitable for driving the LED with a current density at least ten times higher than that of the photodiode.
